(19) United States
(12) Patent Application Publication
(10) Pub. No.: US 2019/0352766 A1
(43) Pub. Date: Nov. 21, 2019

(54) METHOD FOR COATING A METAL COMPONENT WITH AN ANTI-WEAR LAYER, METAL COMPONENT AND FUEL INJECTION SYSTEM

(71) Applicant: Robert Bosch GmbH, Stuttgart (DE)

(72) Inventor: Marcus Guenther, Gerlingen (DE)

(21) Appl. No.: 16/470,725

(22) PCT Filed: Nov. 9, 2017
(86) PCT No.: PCT/EP2017/078769

§ 371 Date: Jun. 18, 2019

(30) Foreign Application Priority Data
Dec. 19, 2016 (DE) 10 2016 225 449.9

(51) Int. Cl. C23C 14/06; C23C 14/02; C23C 14/32

(52) U.S. Cl. CPC C23C 14/0605; C23C 14/022; C23C 14/325; C23C 14/025; C23C 14/028

(57) ABSTRACT

The invention relates to a method for coating a metal component (1) with a hard anti-wear layer (3), which is applied by means of a plasma method at least in a single layer over at least part of the surface of the component (1), wherein droplets (5) deposited on the surface of the applied hard anti-wear layer (3) are mechanically removed, and then a run-in layer (7) that is softer than the anti-wear layer (3) is applied to the surface of the applied and mechanically processed anti-wear layer (3).

### BACKGROUND OF THE INVENTION

The present invention relates to a process for coating a metallic component part with a hard antiwear layer which is applied over at least part of the surface of the component part in at least one layer by a plasma process. The invention further relates to a metallic component part coated therewith and to a fuel injection system of a motor vehicle comprising such metallic component parts as system components.

The field of application of the invention extends especially to motor vehicle technology, in particular to fuel injection systems. Their metallic component parts, for example valve seats of fuel injectors, plain bearing journals in high-pressure pumps and the like, are subjected to high pressures and frictional demands during operation and such tribologically highly stressed surfaces of metallic component parts of interest here are therefore provided with an antiwear layer which markedly reduce in particular the friction values in tribological contacts. Such antiwear layers contain for example chromium nitrite, titanium nitrite or DLC (diamond-like carbon). In addition to injection technology such antiwear layers are also used in tooling technology, i.e. as tool coatings.

Processes for deposition of such antiwear layers which are common knowledge in the prior art are vacuum arc evaporation or PVD processes (PVD=physical vapor deposition).

DE 10 2009 003 192 A1 discloses an antiwear layer assembly applied to the surface of a component part to be protected in a PVD process, preferably under vacuum. The antiwear layer assembly comprises an antiwear layer formed from tetrahedrally-bonded amorphous carbon or comprising a proportion of tetrahedrally-bonded amorphous carbon and a titanium-comprising adhesion-promoting layer between the component and the antiwear layer. In addition to titanium the adhesion-promoting layer further comprises at least one oxidation-resistant element. This reduces the high chemical reactivity of titanium and increases the oxidation-resistance in the adhesion-promoting layer, thus benefiting the resilience of the overall antiwear assembly. The adhesion-promoting layer is also applied in a PVD process.

A consequence of this process is the formation of so-called droplets, i.e. coarse-grained material precipitations protruding from the surface of the coating with a grain size of several micrometers. This disadvantageously increases the surface roughness of the thus-coated metallic component parts which in turn has a negative effect on the friction and wear behavior of the component part.

While such droplets can be reduced by an electromagnetic filtering of the coating particle stream this process is rather costly and complex, in particular as a result of an energy-intensive filter construction. In addition, high-volume application is systemically unachievable which is disadvantageous in respect of the abovedescribed field of application in motor vehicle technology.

In turn, smoothing of the surface of the antiwear layer to remove the droplets leaves behind holes in the layer surface which likewise generate a high roughness but in some cases also reveal the component part surface. Such holes would be weak points for chemical decomposition processes or corrosion.

### SUMMARY OF THE INVENTION

The present invention has for its object to further improve a process for coating a metallic component part with an antiwear layer of the type of interest here, and a metallic component part coated therewith, to allow manufacture of smooth droplet-free surfaces producible in high volume by means of a plasma process.

The invention includes the process-engineering teaching that after the application of a hard antiwear layer to the surface of a component part by a plasma process the thus-deposited droplets are initially mechanically removed in a subsequent step and that subsequently a comparatively softer abradable layer is applied to the surface of the applied and mechanically treated antiwear layer.

In a preferred embodiment the hard antiwear layer is a tetrahedral hydrogen-free amorphous carbon layer (ta-C) while the comparatively softer abradable layer is a hydrogen-containing amorphous carbon layer (a-c:H). This specific material combination in particular has proven to be not only low-friction but also highly resilient on the tribologically highly stressed metallic component parts of interest here.

It is proposed that the abradable layer is likewise applied by a plasma process, wherein the step shall advantageously be preceded by a plasma cleaning or plasma activation process to maximize layer adhesion. The abradable layer is moreover also anchored into the microdents introduced into the antiwear layer surface as a result of the preceding mechanical processing step, thus further improving adhesion.

The mechanical removal of the droplets from the hard antiwear layer performed by the intermediate process step may be performed by polishing or brushing for example. Belt finishing, drag finishing or flow finishing is particularly suitable.

To achieve the highest possible degree of automation for the coating it is proposed that the hard antiwear layer applied to the surface of the component part by a plasma process is applied by pulsed or non-pulsed vacuum arc evaporation. For the softer abradable layer the PVD process or the PECVD process (PECVD=plasma enhanced chemical vapor deposition) may be employed.

In a further measure which improves the invention it is proposed that prior to application of the hard antiwear layer at least one metallic adhesion-promoting layer is applied to the surface of the component part. The adhesion-promoting layer increases the resilience of the hard antiwear layer and may likewise be performed automatically by plasma coating in a vacuum coating plant which for this purpose deposits titanium. The adhesion-promoting layer made of titanium may also be admixed with an oxidation-resistant element to reduce the high chemical reactivity of titanium. Furthermore, the adhesion-promoting layer may also be multi-layered and for example be composed of a first adhesion-promoting layer comprising a chromium proportion and a second adhesion-promoting layer comprising a carbon proportion.

### BRIEF DESCRIPTION OF THE DRAWINGS

Further measures which improve the invention are more particularly elucidated hereinbelow with reference to figures together with the description of the preferred working examples of the invention.

FIG. 1 shows a schematic diagram of a metallic component part subjected to multi-step processing according to the invention in processing steps I to III, and

FIG. 2 shows a process flow diagram for a complete processing step sequence for coating the component part with an antiwear layer.

### DETAILED DESCRIPTION

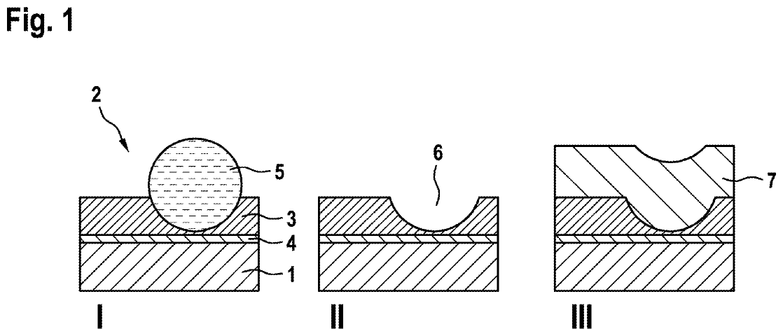

In FIG. 1 a metallic component part 1 shown only schematically here is coated on the side of a tribologically stressed surface 2 with an antiwear layer 3 which is a tetrahedral hydrogen-free amorphous carbon layer (ta-C). This hard antiwear layer 3 is applied to the surface of the component part 1 by a plasma process by means of a metallic adhesion-promoting layer 4. The hard antiwear layer 3 applied in this first process step I has droplets 5 protruding from the surface which result from the employed plasma process and markedly increase surface roughness.

In the subsequent process step II these droplets 5 are removed mechanically by polishing. This results in microdents 6 in the surface of the component 1 provided with the antiwear layer 3.

In the subsequent process step III a comparatively softer abradable layer 7 is applied by a plasma process to the surface of the applied and mechanically processed antiwear layer 3. In this working example the abradable layer 7 which is softer in terms of material hardness than the antiwear layer 3 is a hydrogen-containing amorphous carbon layer (a-C:H). This also causes a flattening of the microdents 6 so that an altogether smoother and thus lower-friction antiwear layer is obtained.

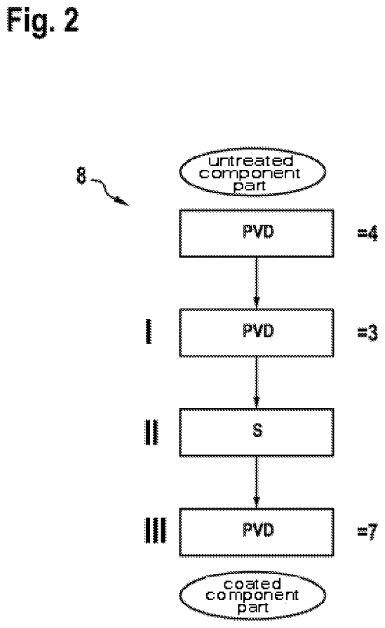

In FIG. 2 the coating of the metallic component part—not shown here—is carried out when in a vacuum coating plant 8 a metallic adhesion-promoting layer 4 is initially applied to the surface of the uncoated metallic component part 1 by a PVD process. Subsequently, in process step I the hard antiwear layer 3 is applied to the adhesion-promoting layer 4 by means of a PVD process. After the mechanical processing a plasma cleaning intermediate process step is carried out. This is followed by a mechanical removal of droplets 5 deposited on the hard antiwear layer 3 by polishing in process step II. Subsequently in a PVD or PECVD process in the same vacuum coating plant 8 the abradable layer 7 which is softer than the hard antiwear layer 3 is applied in process step III. This affords the inventive coating of the metallic component part 1.

1. A process for coating a metallic component part (1) with a hard antiwear layer (3) which is applied over at least part of a surface of the component part (1) in at least one layer by a plasma process, the method comprising
depositing droplets (5) on a surface of the applied hard antiwear layer (3),
mechanically removing the droplets, and
subsequently applying a comparatively softer abradable layer (7) to the surface of the applied and mechanically treated antiwear layer (3).

2. The process as claimed in claim 1,
characterized in that the abradable layer (7) is likewise applied by a plasma process, wherein said plasma process is preceded by a plasma cleaning or plasma activation process step.

3. The process as claimed in claim 1,
characterized in that the mechanical removal of the droplets (5) is performed by polishing or brushing.

4. The process as claimed in claim 1,
characterized in that the hard antiwear layer (3) applied to the surface of the component part (1) by a plasma process and/or the softer abradable layer (7) is/are applied by a PVD or PECVD process.

5. The process as claimed in claim 1,
characterized in that prior to application of the hard antiwear layer (3) at least one metallic adhesion-promoting layer (4) is applied to the surface of the component part (1).

6. The process as claimed in claim 5,
characterized in that the coating steps for applying the abradable layer (7), the antiwear layer (3) and the adhesion-promoting layer (4) are performed in the same vacuum coating plant (8).

7. A metallic component part (1) having a tribologically stressed surface (2) that has been at least partially coated with a hard antiwear layer (3) by a plasma process,
characterized in that a droplet-free surface thereof has a comparatively softer abradable layer (7) arranged thereupon.

8. The metallic component part (1) as claimed in claim 7,
characterized in that the softer abradable layer (7) is a hydrogen-containing amorphous carbon layer (a-C:H).

9. The metallic component part (1) as claimed in claim 7,
characterized in that the hard antiwear layer (3) is a tetrahedral hydrogen-free amorphous carbon layer (ta-C).

10. A fuel injection system of a motor vehicle comprising at least one tribologically stressed metallic component part (1) as claimed in claim 7.

11. The process as claimed in claim 1,
characterized in that the hard antiwear layer (3) applied to the surface of the component part (1) by a plasma process and/or the softer abradable layer (7) is/are applied by vacuum arc evaporation.

12. The process as claimed in claim 1,
characterized in that the coating steps for applying the abradable layer (7) and the antiwear layer (3) performed in the same vacuum coating plant (8).
